(19) United States
(12) Patent Application Publication
(10) Pub. No.: US 2026/0148882 A1
(43) Pub. Date: May 28, 2026

(54) METHODS AND APPARATUS TO SET A BODY BIAS OF A RESISTOR

(71) Applicant: Texas Instruments Incorporated, Dallas, TX (US)

(72) Inventors: Zhenzhen Chen, Shanghai (CN); Jianquan Liao, Shanghai (CN); Kannan Krishna, Dallas, TX (US); Zejian Wang, Shanghai (CN); Xinyuan Geng, Shanghai (CN)

(21) Appl. No.: 18/963,090

(22) Filed: Nov. 27, 2024

(51) Int. Cl. H01C 1/16; H03K 17/56

(52) U.S. Cl. CPC H01C 1/16; H03K 17/56

(57) ABSTRACT

An example apparatus includes: a first resistor having a first terminal and a bias terminal; a second resistor having a first terminal and a bias terminal; and bias circuitry including: a third resistor having a first terminal and a second terminal, the first terminal of the third resistor coupled to the first terminal of the first resistor; a fourth resistor having a first terminal and a second terminal, the first terminal of the fourth resistor coupled to the bias terminal of the first resistor and the second terminal of the third resistor; a fifth resistor having a first terminal and a second terminal, the first terminal of the fifth resistor coupled to the first terminal of the second resistor; a sixth resistor having a first terminal coupled to the bias terminal of the second resistor and the second terminal of the fifth resistor; and buffer circuitry.

### TECHNICAL FIELD

This description relates generally to resistors and, more particularly, to methods and apparatus to set a body bias of a resistor.

### BACKGROUND

Electronic systems utilize amplifier circuitry for a wide range of operations, such as for signal modulation. In audio systems, amplifier circuitry modulates a carrier signal based on an information signal to generate a modulated output signal. The modulated output signal is a relatively higher power signal and has relatively high noise immunity in comparison to the information signal. Some amplifier circuitry has a feedback path, which improves the modulation of the information signal. Such amplifier circuitry is referred to as closed loop amplifier circuitry that utilizes a feedback resistor coupled between an input and an output to form the feedback path. The resistance of the feedback resistor sets amplifier gain, stabilizes timing, controls bandwidth, etc.

### SUMMARY

For methods and apparatus to set a body bias of a resistor, an example apparatus includes a first resistor having a first terminal and a bias terminal; a second resistor having a first terminal and a bias terminal; and bias circuitry including: a third resistor having a first terminal and a second terminal, the first terminal of the third resistor coupled to the first terminal of the first resistor; a fourth resistor having a first terminal and a second terminal, the first terminal of the fourth resistor coupled to the bias terminal of the first resistor and the second terminal of the third resistor; a fifth resistor having a first terminal and a second terminal, the first terminal of the fifth resistor coupled to the first terminal of the second resistor; a sixth resistor having a first terminal and a second terminal, the first terminal of the sixth resistor coupled to the bias terminal of the second resistor and the second terminal of the fifth resistor; and buffer circuitry having an output coupled to the second terminal of the fourth resistor and the second terminal of the sixth resistor. Other examples are described.

For methods and apparatus to set a body bias of a resistor, an example apparatus includes amplifier circuitry having a first input, a second input, a first output, and a second output; a first resistor having a first terminal, a second terminal, and a bias terminal, the first terminal of the first resistor coupled to the first input of the amplifier circuitry; a second resistor having a first terminal, a second terminal, and a bias terminal, the first terminal of the second resistor coupled to the second input of the amplifier circuitry; and bias circuitry having a first input, a second input, a first output, and a second output, the first input of the bias circuitry coupled to the first output of the amplifier circuitry and the second terminal of the first resistor, the second input of the bias circuitry coupled to the second output of the amplifier circuitry and the second terminal of the second resistor, the first output of the bias circuitry coupled to the bias terminal of the first resistor, the second output of the bias circuitry coupled to the bias terminal of the second resistor. Other examples are described.

For methods and apparatus to set a body bias of a resistor, an example apparatus includes a first resistor having a first terminal and a bias terminal; a second resistor having a first terminal and a bias terminal; a third resistor having a first terminal and a second terminal, the first terminal of the third resistor coupled to the first terminal of the first resistor; first buffer circuitry having an input and an output, the output of the first buffer circuitry coupled to the bias terminal of the first resistor; a fourth resistor having a first terminal and a second terminal, the first terminal of the fourth resistor coupled to the second terminal of the third resistor and the input of the first buffer circuitry; a fifth resistor having a first terminal and a second terminal, the first terminal of the fifth resistor coupled to the first terminal of the second resistor; second buffer circuitry having an input and an output, the output of the second buffer circuitry coupled to the bias terminal of the second resistor; and a sixth resistor having a first terminal and a second terminal, the first terminal of the sixth resistor coupled to the second terminal of the fifth resistor and the input of the fifth resistor, the second terminal of the sixth resistor coupled to the second terminal of the fourth resistor. Other examples are described.

### BRIEF DESCRIPTION OF THE DRAWINGS

FIG. 1 is a block diagram of an example amplifier system including example bias circuitry.

FIG. 2 is a block diagram of an example audio system including example multi-class modulation circuitry and example bias circuitry.

FIG. 3 is a block diagram of an example bias system including an example polysilicon implementation of a resistor and an example of the bias circuitry of FIGS. 1 and 2.

FIG. 4 is a schematic diagram of an example of the bias system of FIG. 3 including an example of the resistor of FIG. 3 and an example of the bias circuitry of FIGS. 1, 2, and 3.

FIG. 5 is a schematic diagram of an example the bias system of FIG. 3 including an example of the bias circuitry of FIGS. 1, 2, and 3.

FIG. 6 is a schematic diagram of an example the bias systems of FIGS. 3 and 5 including an example of the bias circuitry of FIGS. 1, 2, 3, and 5 and example common mode buffer circuitry.

FIG. 7 is a schematic diagram of an example of the bias systems of FIGS. 3, 5, and 6 including an example of the bias circuitry of FIGS. 1, 2, 3, 5, and 6 and example trim control circuitry.

FIG. 8 is a schematic diagram of an example of the bias systems of FIGS. 3, 5, 6, and 7 including an example of the bias circuitry of FIGS. 1, 2, 3, 5, 6, and 7 and example bias buffer circuitry.

FIG. 9 is a flowchart representative of example machine-readable instructions or example operations that may be at least one of executed, instantiated, or performed using an example implementation of the bias circuitry of FIGS. 1, 2, 3, 4, 5, 6, 7, and 8 or more generally the amplifier system of FIG. 1 or the audio system of FIG. 2.

FIG. 10 is a plot of example total harmonic distortion (THD) versus power of feedback resistors with and without the bias circuitry of FIGS. 1, 2, 3, 4, 5, 6, 7, and 8.

FIG. 11 is a plot of example power supply rejection ratio (PSRR) with the bias circuitry of FIGS. 1, 2, 3, 4, 5, 6, 7, and 8.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Electronic systems utilize amplifier circuitry for a wide range of operations, such as for signal modulation. In audio systems, amplifier circuitry modulates a carrier signal based on an information signal to generate a modulated output signal. The modulated output signal is a relatively higher power signal and has relatively high noise immunity in comparison to the information signal. Some amplifier circuitry has a feedback path, which improves the modulation of the information signal. Such amplifier circuitry is referred to as closed loop amplifier circuitry that utilizes a feedback resistor coupled between an input and an output to form the feedback path. The resistance of the feedback resistor sets amplifier gain, stabilizes timing, controls bandwidth, etc.

In some designs, integrated circuits (ICs) implement resistors using doped polycrystalline silicon (also referred to as polysilicon) or other process technologies. Such resistors are referred to as polysilicon resistors. A polysilicon resistor includes a substrate, a body, an oxide, and a polysilicon layer. The substrate supports and isolates the body from other portions of the IC, such as portions of the substrate with the same type of doping as the body. The body is a doped semiconductor material that supports the oxide and the polysilicon layer. The doping of the body is opposite of the doping of both the substrate and the polysilicon layer. The body increases the voltage rating of the polysilicon resistor by increasing the breakdown voltage between the polysilicon layer and the substrate. The oxide electrically isolates the polysilicon layer from the body and facilitates thermal dissipation of heat from the polysilicon layer. The polysilicon layer is coupled to external circuitry by terminals. The doping of the polysilicon layer is specific to achieving the target resistance of the polysilicon resistor.

By controlling the doping of the polysilicon layer, polysilicon resistors can have relatively high accuracy resistances. However, during operation, the resistance of polysilicon resistors has first and second order voltage coefficients that change the resistance of the polysilicon layer. The first order voltage coefficient (also referred to as body bias) changes the resistance of a polysilicon resistor based on the voltage difference between the body and polysilicon layer. During operation, as the circuitry sets the polysilicon layer to different voltages, the voltage difference of the first order voltage coefficient changes the resistance of the polysilicon resistor. The second order voltage coefficient (also referred to as self-heating) changes the resistance of the polysilicon resistor based on the temperature of the polysilicon layer. During operation, as the polysilicon resistor consumes power, the temperature increases, which changes the resistance of the polysilicon layer.

In some devices, such as closed loop amplifiers and audio amplifiers, changing the feedback resistance during operation makes the gain voltage dependent. Also, in fully differential amplifiers that have multiple feedback resistors, the variation in feedback resistances increases the THD and reduces PSRR. In audio systems, relatively high THD results in audible distortions. Similarly, relatively low PSRR may result in noise in the audible frequency range (e.g., 20 Hz to 20 kHz) from the power supply of the audio system being present at the output.

Some designers reduce the impact of the first order voltage coefficient on resistance by biasing the body of the polysilicon resistor to a fixed bias voltage. In such designs, the body of the polysilicon resistor has a terminal, which may be referred to as a bias terminal. To reduce the voltage difference of the first order voltage coefficient across operating conditions, designers set a fixed bias voltage to a voltage between the maximum voltage applied to the polysilicon layer (also known as a breakdown voltage) and a target input voltage. Such a bias voltage reduces the maximum voltage difference between the polysilicon layer and the body across operating conditions. However, setting the bias voltage too high may create parasitic capacitances between the body and substrate of the polysilicon resistor. The parasitic capacitance creates a resistor-capacitor circuit having a time constant that limits the bandwidth of circuitry.

Examples described herein include methods and apparatus to set a body bias of a resistor. In some described examples, an example bias system includes a first resistor, a second resistor, and bias circuitry. The first and second resistors are polysilicon resistors having first and second terminals coupled to the polysilicon layer and a bias terminal coupled to the body. In a closed loop amplifier system, the first terminals of the first and second resistors are coupled to the outputs of the amplifier circuitry. Similarly, the second terminals of the first and second resistors are coupled to the inputs of the amplifier circuitry. In example operation, the first terminals of the first and second resistors are set to the relatively high output voltages of the amplifier circuitry and the second terminals of the first and second resistors are set to the relatively low input voltages of the amplifier circuitry. The bias circuitry is coupled to the first and bias terminals of the first and second resistors.

In some described examples, the bias circuitry includes a third resistor, a fourth resistor, a fifth resistor, a sixth resistor, and buffer circuitry. The buffer circuitry buffers a reference common mode voltage. In some examples, such as in the closed loop amplifier system, the reference common mode voltage represents the target common mode voltage of the input signals. In such examples, the closed loop amplifier system may include common mode circuitry to set the reference common mode voltage based on the inputs of the amplifier circuitry. The third and fourth resistors produce a plus bias voltage responsive to dividing the difference between the voltage at the first terminal of the first resistor and the buffered common mode voltage. The bias circuitry biases the first resistor by setting the body equal to the plus bias voltage. The fifth and sixth resistors produce a minus bias voltage responsive to dividing the difference between the voltage at the first terminal of the second resistor and the buffered common mode voltage. The bias circuitry biases the second resistor by setting the body equal to the minus bias voltage.

Advantageously, biasing the first and second resistors based on the voltage difference across the first and second resistors reduces the first order voltage coefficient of the resistances of the first and second resistors. Advantageously, decreasing the change in resistance of the first and second resistors reduces the THD and increases the PSRR of amplifier systems.

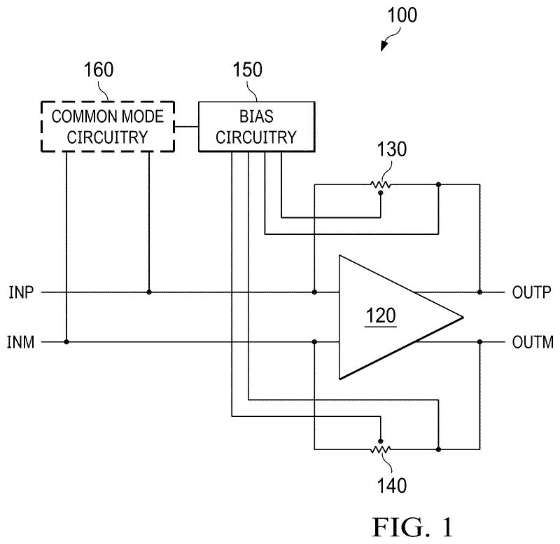

FIG. 1 is a block diagram of an example amplifier system 100. In the example of FIG. 1, the amplifier system 100 includes amplifier circuitry 120, a first resistor 130, a second resistor 140, bias circuitry 150, and may include common mode circuitry 160 in some examples. The amplifier system 100 has a first input, a second input, a first output, and a second output. The first and second inputs of the amplifier system 100 are structured to be coupled to an analog signal source, such as an audio source or digital-to-analog converter (DAC). In the example of FIG. 1, the amplifier system 100 is structured to receive plus and minus input signals (INP, INM) at the first and second inputs of the amplifier system 100. The plus and minus input signals are a pair of signals representing an analog signal to be modulated by the amplifier system 100. The first and second outputs of the amplifier system 100 are structured to be coupled to external circuitry, such as a speaker or signal processing device. In the example of FIG. 1, the amplifier system 100 generates plus and minus output signals (OUTP, OUTM) at the first and second outputs of the amplifier circuitry 120. The plus and minus output signals are a pair of signals representing a modulated version of the plus and minus input signals.

The amplifier circuitry 120 has a first terminal, a second terminal, a third terminal, and a fourth terminal. The first terminal of the amplifier circuitry 120 is coupled to the resistor 130, the common mode circuitry 160, and the first input of the amplifier system 100, which supplies the plus input signal (INP). The second terminal of the amplifier circuitry 120 is coupled to the resistor 140, the common mode circuitry 160, and the second input of the amplifier system 100, which supplies the minus input signal (INM). The third terminal of the amplifier circuitry 120 is coupled to the resistor 130, the bias circuitry 150, and the first output of the amplifier system 100, which supplies the plus output signal (OUTP). The fourth terminal of the amplifier circuitry 120 is coupled to the resistor 140, the bias circuitry 150, and the second output of the amplifier system 100, which supplies the minus output signal (OUTM).

The resistor 130 has a first terminal, a second terminal, and a bias terminal. The first terminal of the resistor 130 is coupled to the amplifier circuitry 120, the common mode circuitry 150, and the first input of the amplifier system 100, which supplies the plus input signal (INP). The second terminal of the resistor 130 is coupled to the amplifier circuitry 120, the bias circuitry 150, and the first output of the amplifier system 100, which supplies the plus output signal (OUTP). The bias terminal of the resistor 130 is coupled to the bias circuitry 150.

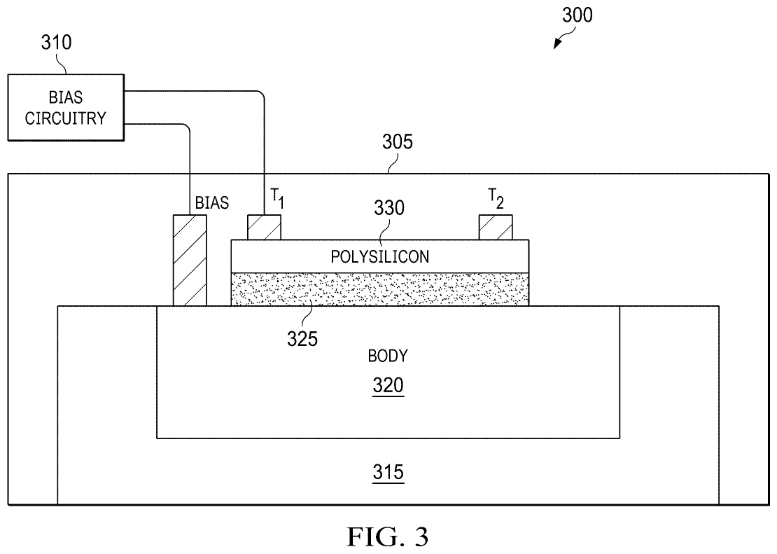

The resistor 140 has a first terminal, a second terminal, and a bias terminal. The first terminal of the resistor 140 is coupled to the amplifier circuitry 120, the common mode circuitry 160, and the second input of the amplifier system 100, which supplies the minus input signal (INM). The second terminal of the resistor 140 is coupled to the amplifier circuitry 120, the bias circuitry 150, and the second output of the amplifier system 100, which supplies the minus output signal (OUTM). The bias terminal of the resistor 140 is coupled to the bias circuitry 150. In the example of FIG. 1, the resistors 130, 140 are polysilicon resistors. An example implementation of the resistors 130, 140 as an example polysilicon resistor is further illustrated and described in connection with FIG. 3.

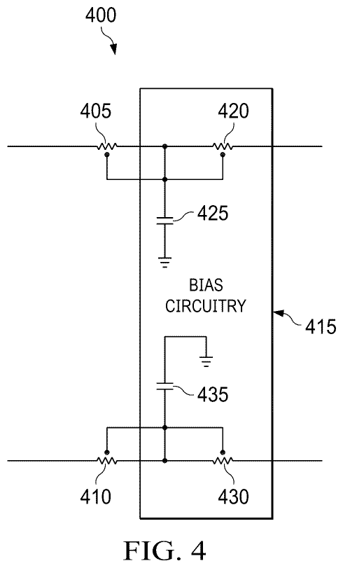

The bias circuitry 150 has a first terminal, a second terminal, a third terminal, a fourth terminal, and a fifth terminal. The first terminal of the bias circuitry 150 is coupled to the amplifier circuitry 120, the resistor 130, and the first output of the amplifier system 100, which supplies the plus output signal (OUTP). The second terminal of the bias circuitry 150 is coupled to the resistor 130. The third terminal of the bias circuitry 150 is coupled to the amplifier circuitry 120, the resistor 140, and the second output of the amplifier system 100, which supplies the minus output signal (OUTM). The fourth terminal of the bias circuitry 150 is coupled to the resistor 140. The fifth terminal of the bias circuitry 150 is coupled to the common mode circuitry 160. Examples of the bias circuitry 150 are further illustrated and described in connection with FIGS. 4, 5, 6, 7, and 8.

The common mode circuitry 160 has a first terminal, a second terminal, and a third terminal. The first terminal of the common mode circuitry 160 is coupled to the amplifier circuitry 120, the resistor 130, and the first input of the amplifier system 100, which supplies the plus input signal (INP). The second terminal of the common mode circuitry 160 is coupled to the amplifier circuitry 120, the resistor 140, and the second input of the amplifier system 100, which supplies the minus input signal (INM). The third terminal of the common mode circuitry 160 is coupled to the bias circuitry 150. In some examples, the common mode circuitry 160 is a voltage divider. In other examples, the common mode circuitry 160 is replaced with a fixed reference voltage, which represents a target common mode voltage at the inputs of the amplifier system 100.

In example operations, the amplifier circuitry 120 receives the plus and minus input signals from an external signal source. The amplifier circuitry 120 at least one of amplifies or modulates the plus and minus input signals to generate the plus and minus output signals. In such example operations, the resistors 130, 140 supply feedback currents to the inputs of the amplifier system 100 to increase the accuracy of the plus and minus output signals.

In example operations, the common mode circuitry 160 determines the common mode voltage of the plus and minus input signals to provide a reference common mode voltage. The bias circuitry 150 generates a plus bias voltage based on the difference between the reference common mode voltage and the voltage of the plus output signal. The bias circuitry 150 biases the resistor 130 using the plus bias voltage. The bias circuitry 150 generates a minus bias voltage based on the difference between the reference common mode voltage and the voltage of the minus output signal. The bias circuitry 150 biases the resistor 140 using the minus bias voltage. Advantageously, the bias circuitry 150 adjusts the plus and minus bias voltages as the voltages of the plus and minus output signals change. Advantageously, biasing the resistors 130, 140 based on the voltages of the plus and minus output signals reduces the impact of the first order voltage coefficient on the resistance of the resistors 130, 140.

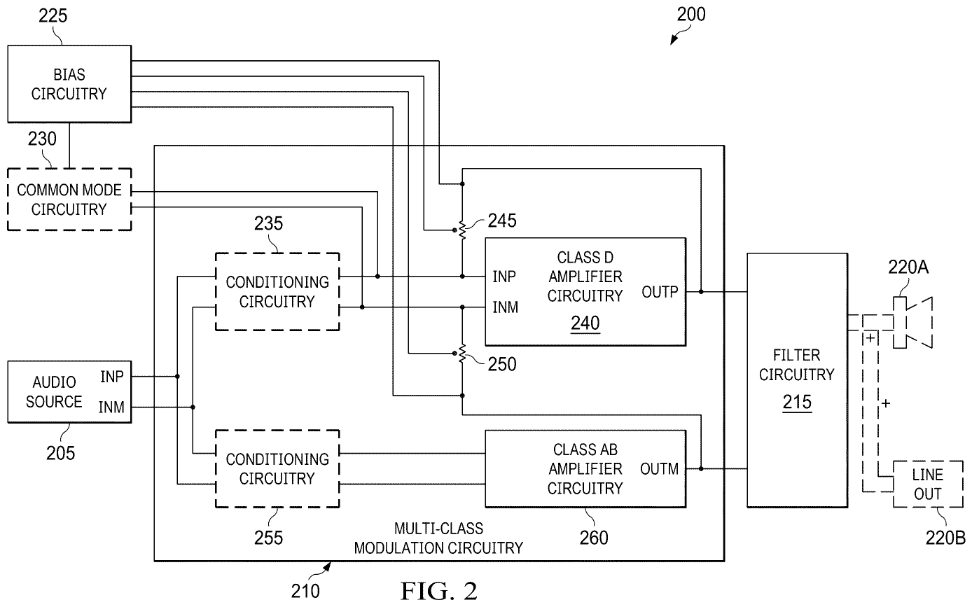

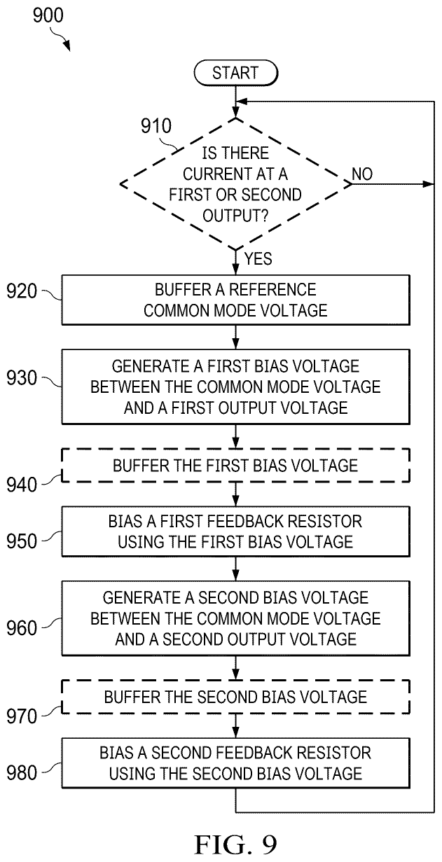

Example operations of the amplifier system 100 are further illustrated and described in connection with FIG. 9. Also, FIG. 2 illustrates and describes an alternative example of the amplifier system 100, which is structured to implement a modulation technique. Alternatively, the amplifier system 100 may be modified to implement another type of signal modulation.

FIG. 2 is a block diagram of an example audio system 200, which is an example implementation of the amplifier system 100 of FIG. 1. In the example of FIG. 2, the audio system 200 includes an example audio source 205, example multi-class modulation circuitry 210, example filter circuitry 215, an example speaker 220A, an example line out port 220B, example bias circuitry 225, and may include example common mode circuitry 230 in some examples. The example multi-class modulation circuitry 210 of FIG. 2 includes first example amplifier circuitry 240, a first example resistor 245, a second example resistor 250, and second example amplifier circuitry 260 and may include first example conditioning circuitry 235 and second example conditioning circuitry 255 in some examples.

In the example of FIG. 2, the audio system 200 is structured to implement single inductor (1L) modulation. Examples of the amplifier circuitry 240, 260 or more generally the multi-class modulation circuitry 210 of FIG. 2, or even more generally the audio system 200 are further illustrated and described in “METHODS AND APPARATUS TO MODULATE SIGNALS USING MULTI-CLASS MODULATION CIRCUITRY” U.S. patent application Ser. No. 18/385,848, which is incorporated by reference in its entirety and is assigned to the assignee of the instant application.

The audio source 205 has a first terminal and a second terminal. The first and second terminals of the audio source 205 are coupled to multi-class modulation circuitry 210. In the example of FIG. 2, the audio source 205 is structured as an analog signal source. In some examples, the audio source 205 is a digital-to-analog converter (DAC). In such examples, the audio source 205 has an input coupled to digital signal processing circuitry, which supplies digital audio signals.

The multi-class modulation circuitry 210 has a first terminal, a second terminal, a third terminal, a fourth terminal, a fifth terminal, a sixth terminal, a seventh terminal, and an eighth terminal. The first and second terminals of the multi-class modulation circuitry 210 are coupled to the audio source 205. The third and fourth terminals of the multi-class modulation circuitry 210 are coupled to the common mode circuitry 230. The fifth and sixth terminals of the multi-class modulation circuitry 210 are coupled to the filter circuitry 215 and the bias circuitry 225. The eighth and ninth terminals of the multi-class modulation circuitry 210 are coupled to the bias circuitry 225.

The filter circuitry 215 has a first terminal, a second terminal, a third terminal, and a fourth terminal. The first and second terminals of the filter circuitry 215 are coupled to the multi-class modulation circuitry 210 and the bias circuitry 225. The third and fourth terminals of the filter circuitry 215 may be coupled to one or more of the speaker 220A or the line out port 220B.

The speaker 220A has a first terminal and a second terminal. The first and second terminals of the speaker 220A are coupled to the filter circuitry 215 and may be coupled to the line out port 220B. The line out port 220B has a first terminal and a second terminal. The first and second terminals of the line out port 220B are coupled to the filter circuitry 215 and may be coupled to the speaker 220A. In some examples, the audio system 200 includes at least one of the speaker 220A or the line out port 220B.

The bias circuitry 225 has a first terminal, a second terminal, a third terminal, a fourth terminal, and a fifth terminal. The first terminal of the bias circuitry 225 is coupled to the filter circuitry 215, the class D amplifier circuitry 240, and the resistor 245. The second terminal of the bias circuitry 225 is coupled to the resistor 245. The third terminal of the bias circuitry 225 is coupled to the filter circuitry 215, the resistor 250, and the class AB amplifier circuitry 260. The fourth terminal of the bias circuitry 225 is coupled to the resistor 250. The fifth terminal of the bias circuitry 225 is coupled to the common mode circuitry 230. The bias circuitry 225 is an example of the bias circuitry 150 of FIG. 1. Examples of the bias circuitry 225 are further illustrated and described in connection with FIGS. 4, 5, 6, 7, and 8.

The common mode circuitry 230 has a first terminal, a second terminal, and a third terminal. The first terminal of the common mode circuitry 230 is coupled to the conditioning circuitry 235, the class D amplifier circuitry 240, and the resistor 245. The second terminal of the common mode circuitry 230 is coupled to the conditioning circuitry 235, the class D amplifier circuitry 240, and the resistor 250. The third terminal of the common mode circuitry 230 is coupled to the bias circuitry 225. In some examples, the common mode circuitry 230 is a voltage divider. In other examples, the common mode circuitry 230 is replaced with a fixed reference voltage, which represents a target common mode voltage at the inputs of the multi-class modulation circuitry 210. The common mode circuitry 230 is an example of the common mode circuitry 160 of FIG. 1.

The conditioning circuitry 235 has a first terminal, a second terminal, a third terminal, and a fourth terminal. The first and second terminals of the conditioning circuitry 235 are coupled to the audio source 205 and the conditioning circuitry 255. The third terminal of the conditioning circuitry 235 is coupled to the common mode circuitry 230, the class D amplifier circuitry 240, and the resistor 245. The fourth terminal of the conditioning circuitry 235 is coupled to the common mode circuitry 230, the class D amplifier circuitry 240, and the resistor 250.

The class D amplifier circuitry 240 has a first terminal, a second terminal, and a third terminal. The first terminal of the class D amplifier circuitry 240 is coupled to the common mode circuitry 230, the conditioning circuitry 235, and the resistor 245. The second terminal of the class D amplifier circuitry 240 is coupled to the common mode circuitry 230, the conditioning circuitry 235, and the resistor 250. The third terminal of the class D amplifier circuitry 240 is coupled to the bias circuitry 225, the filter circuitry 215, and the resistor 245.

The resistor 245 has a first terminal, a second terminal, and a bias terminal. The first terminal of the resistor 245 is coupled to the common mode circuitry 230, the conditioning circuitry 235, and the class D amplifier circuitry 240. The second terminal of the resistor 245 is coupled to the bias circuitry 225, the filter circuitry 215, and the class D amplifier circuitry 240. The bias terminal of the resistor 245 is coupled to the bias circuitry 225. In some examples, the resistor 245 is referred to as a feedback resistor (R_{fb}).

The resistor 250 has a first terminal, a second terminal, and a bias terminal. The first terminal of the resistor 250 is coupled to the common mode circuitry 230, the conditioning circuitry 235, and the class D amplifier circuitry 240. The second terminal of the resistor 250 is coupled to the bias circuitry 225, the filter circuitry 215, the class D amplifier circuitry 240, and the class AB amplifier circuitry 260. The bias terminal of the resistor 250 is coupled to the bias circuitry 225. In some examples, the resistor 250 is referred to as a feedback resistor (R_{fb}). In the example of FIG. 2, the resistors 245, 250 are polysilicon resistors having a polysilicon layer coupled to the first and second terminals and a body coupled to the bias terminal. An example implementation of the resistors 245, 250 as a polysilicon resistor is further illustrated and described in connection with FIG. 3.

The conditioning circuitry 255 has a first terminal, a second terminal, a third terminal, and a fourth terminal. The first and second terminals of the conditioning circuitry 255 are coupled to the audio source 205 and the conditioning circuitry 235. The third and fourth terminals of the conditioning circuitry 255 are coupled to the class AB amplifier circuitry 260. In some examples, the conditioning circuitry 235, 255 are at least one of resistors or filters.

The class AB amplifier circuitry 260 has a first terminal, a second terminal, and a third terminal. The first and second terminals of the class AB amplifier circuitry 260 are coupled to the conditioning circuitry 255. The third terminal of the class AB amplifier circuitry 260 is coupled to the bias circuitry 225, the filter circuitry 215, the class D amplifier circuitry 240, and the resistor 250.

In example operation, the audio source 205 supplies the plus and minus input signals (INP, INM) to the multi-class modulation circuitry 210. In the example of FIG. 2, the plus and minus input signals represent an audio signal that, when supplied to the speaker 220A, corresponds to audible sound. In some examples, the conditioning circuitry 235, 255 filters the plus and minus input signals to reduce noise. The class D amplifier circuitry 240 receives the plus and minus input signals. The plus input signal of the class D amplifier circuitry 240 includes contributions from feedback current from the resistor 245. The minus input signal of the class D amplifier circuitry 240 includes contributions from feedback current from the resistor 250. The class D amplifier circuitry 240 modulates the differential pair of amplifier input signals to generate a plus output signal (OUTP). The class AB amplifier circuitry 260 modulates the plus and minus input signals to generate a minus output signal (OUTM). The filter circuitry 215 supplies an amplified audio signal to the speaker 220A and the line out port 220B by filtering the plus and minus output signals.

In example operations, the resistors 245, 250 form feedback paths between the inputs of the class D amplifier circuitry 240 and the outputs of the multi-class modulation circuitry 210. The feedback currents through the resistors 245, 250 are proportional to the differences between voltages of the plus and minus input signals and the plus and minus output signals. In such examples, the bias circuitry 225 receives the reference common mode voltage of the input of the multi-class modulation circuitry 210 from one of the common mode circuitry 230 or a reference terminal. The bias circuitry 225 generates a plus bias voltage based on the difference between the reference common mode voltage and the voltage of the plus output signal. The bias circuitry 225 biases the resistor 245 using the plus bias voltage. The bias circuitry 225 generates a minus bias voltage based on the difference between the reference common mode voltage and the voltage of the minus output signal. The bias circuitry 225 biases the resistor 250 using the minus bias voltage. Example operations of the bias circuitry 225 are further illustrated and described in connection with FIG. 9.

FIG. 3 is a block diagram of an example bias system 300 including an example polysilicon resistor 305 and example bias circuitry 310. The example polysilicon resistor 305 of FIG. 3 includes an example substrate 315, an example body 320, an example oxide layer 325, and an example polysilicon layer 330. The bias circuitry 310 represents an example of the bias circuitry 160, 225 of FIG. 2. In the example of FIG. 3, the bias system 300 illustrates an implementation of the polysilicon resistor 305 in an IC.

The polysilicon resistor 305 has a first terminal, a second terminal, and a bias terminal. The first terminal (T₁) of the polysilicon resistor 305 is coupled to the bias circuitry 310 and is structured to be coupled to the output of amplifier circuitry, such as the amplifier circuitry 120, 240, 260 of FIGS. 1 and 2. The second terminal (T₂) of the polysilicon resistor 305 is structured to be coupled to the input of amplifier circuitry, such as the amplifier circuitry 120, 240, 260. The bias terminal (BIAS) of the polysilicon resistor 305 is coupled to the bias circuitry 310. In the example of FIG. 3, the polysilicon resistor 305 represents a polysilicon implementation of one of the resistors 130, 140, 245, 250 of FIGS. 1 and 2. In some examples, at least one of the structure or materials of the polysilicon resistor 305 may be modified responsive to changes in process technologies, design considerations, etc. For example, the doping of the substrate 315, the body 320, or the polysilicon layer 330 may be modified.

The bias circuitry 310 has a first terminal and a second terminal. The first terminal of the bias circuitry 310 is coupled to the polysilicon layer 330 of the polysilicon resistor 305. The second terminal of the bias circuitry 310 is coupled to the body 320 of the polysilicon resistor 305. The bias circuitry 310 is an example of the bias circuitry 150, 225 of FIGS. 1 and 2. In some examples, the bias circuitry 310 includes additional terminals (illustrated in FIGS. 1 and 2) coupled to one or more additional resistors. Examples of such bias circuitry are further illustrated and described in connection with FIGS. 4, 5, 6, 7, and 8.

The substrate 315 is a doped region structured to at least one of isolate the body 320 from another substrate or support the body 320. In some examples, the substrate 315 is an epitaxial (epi) wafer, which is a semiconductor material doped to isolate the body 320 from another similarly doped substrate region.

The body 320 is a doped well region. In some examples, the body 320 is an n-doped semiconductor material (also referred to as an NWELL). In such examples, the substrate 315 is a p-doped semiconductor material. Also, the body 320 increases the breakdown voltage of the polysilicon resistor 305 by increasing the distance between the polysilicon layer 330 and the substrate 315.

The oxide layer 325 is a supporting layer between the body 320 and the polysilicon layer 330. The oxide layer 325 electrically isolates the substrate 315 and the body 320 from the polysilicon layer 330. The oxide layer 325 may also modify the thermal dissipation of heat from the polysilicon layer 330. In some examples, the oxide layer 325 is a structural component that supports the polysilicon layer 330.

The polysilicon layer 330 is a semiconductor material that has been doped based on a physical characteristic of the polysilicon. In the example of FIG. 3, the polysilicon layer 330 is doped to produce a target resistance. Advantageously, using polysilicon as an analog component improves the accuracy of the analog component. Although in the example of FIG. 3 a single polysilicon resistor is illustrated, ICs often include a plurality of polysilicon resistors coupled by conductive routings. Advantageously, polysilicon resistors reduce manufacturing complexity by utilizing process technologies to form a resistor opposed to having an external component manufactured.

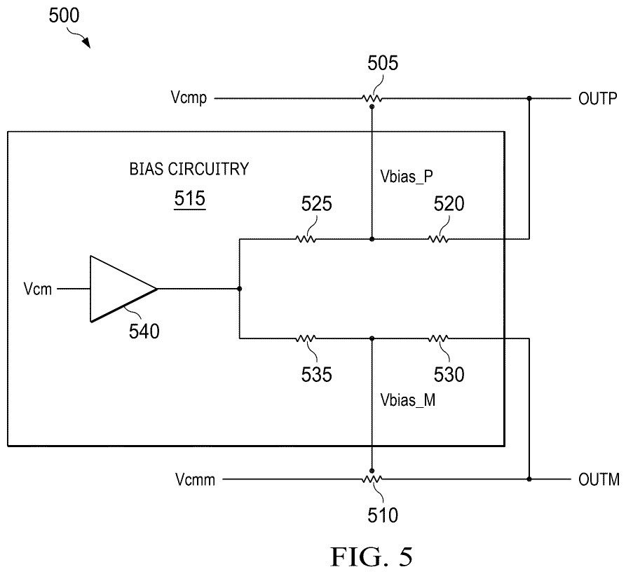

FIG. 4 is a schematic diagram of an example bias system 400 including a first example resistor 405, a second example resistor 410, and example bias circuitry 415. The example bias circuitry 415 of FIG. 4 includes a first example resistor 420, a first example capacitor 425, a second example resistor 430, and a second example capacitor 435. Unlike the bias circuitry of FIGS. 5, 6, 7, and 8, the bias circuitry 415 is coupled in line with the resistors 405, 410.

The resistor 405 has a first terminal, a second terminal, and a bias terminal. The first terminal of the resistor 405 is coupled to the bias circuitry 415. The second terminal of the resistor 405 is structured to be coupled to one of an input or output of amplifier circuitry, such as the amplifier circuitry 120, 240, 260 of FIGS. 1 and 2. The bias terminal of the resistor 405 is coupled to the bias circuitry 415.

The resistor 410 has a first terminal, a second terminal, and a bias terminal. The first terminal of the resistor 410 is coupled to the bias circuitry 415. The second terminal of the resistor 410 is structured to be coupled to one of an input or output of amplifier circuitry, such as the amplifier circuitry 120, 240, 260. The bias terminal of the resistor 410 is coupled to the bias circuitry 415.

The bias circuitry 415 has a first terminal, a second terminal, a third terminal, and a fourth terminal. The first terminal of the bias circuitry 415 is coupled to the resistor 405. The second terminal of the bias circuitry 415 is coupled to the resistor 410. The third terminal of the bias circuitry 415 is structured to be coupled to an input or output of amplifier circuitry, such as the amplifier circuitry 120, 240, 260. The fourth terminal of the bias circuitry 415 is structured to be coupled to an input or output of amplifier circuitry, such as the amplifier circuitry 120, 240, 260. The bias circuitry 415 is an example of the bias circuitry 150, 225, 310 of FIGS. 1, 2, and 3.

The resistor 420 has a first terminal, a second terminal, and a bias terminal. The first and bias terminals of the resistor 420 are coupled to the resistor 405 and the capacitor 425. The second terminal of the resistor 420 is structured to be coupled to an input or output of amplifier circuitry, such as the amplifier circuitry 120, 240, 260. In the example of FIG. 4, the combined resistance of the resistors 405, 420 are an example of one of the resistors 130, 140, 245, 250 of FIGS. 1 and 2. However, unlike the resistors 130, 140, 245, 250, the resistors 405, 420 divide the total feedback resistance to produce a bias voltage between the input and output voltages.

The capacitor 425 has a first terminal and a second terminal. The first terminal of the capacitor 425 is coupled to the resistors 405, 420. The second terminal of the capacitor 425 is coupled to a common terminal, which supplies a common potential (e.g., ground, AVSS, etc.).

The resistor 430 has a first terminal, a second terminal, and a bias terminal. The first and bias terminals of the resistor 430 are coupled to the resistor 410 and the capacitor 435. The second terminal of the resistor 430 is structured to be coupled to an input or output of amplifier circuitry, such as the amplifier circuitry 120, 240, 260. In the example of FIG. 4, the combined resistance of the resistors 410, 430 are an example of one of the resistors 130, 140, 245, 250 of FIGS. 1 and 2. However, unlike the resistors 130, 140, 245, 250, the resistors 410, 430 divide the total feedback resistance to produce a bias voltage between the input and output voltages.

The capacitor 435 has a first terminal and a second terminal. The first terminal of the capacitor 435 is coupled to the resistors 410, 430. The second terminal of the capacitor 435 is coupled to the common terminal, which supplies the common potential. In the example of FIG. 4, the capacitors 425, 435 are illustrated as discrete components. However, in some examples, the capacitors 425, 435 are illustrated or described as an equivalent capacitance formed between the substrate 315 of FIG. 3 and the body 320 of FIG. 3 of the polysilicon implementations of the resistors 405, 410, 420, 430. In such examples, the capacitors 425, 435 may not be illustrated or described.

In example operations, the resistors 405, 420 divide the difference between plus input and output voltages to produce a plus bias voltage. The resistors 405, 420 are biased to the plus bias voltage. Similarly, the resistors 410, 430 divide the difference between minus input and output voltages to produce a minus bias voltage. The resistors 410, 430 are biased to the minus bias voltage. Advantageously, separating the feedback resistances into the resistors 405, 420 and the resistors 410, 430 produces bias voltage between the voltages applied across the polysilicon layer (e.g., the polysilicon layer 330 of FIG. 3) of the resistors 405, 410, 420, 430. Advantageously, biasing the resistors 405, 410, 420, 430 using a voltage between the total voltage difference along the feedback path reduces the first order voltage coefficient of the resistance of the resistors 405, 410, 420, 430. Advantageously, reducing the first order voltage coefficient of the resistance of the resistors 405, 410, 420, 430 reduces errors resulting from changes in feedback resistances.

However, coupling the multiple bodies of polysilicon resistors, such as the coupling the bias terminals of the resistors 405, 420 or the resistors 410, 430, structures parasitic capacitances in parallel. In parallel, the parasitic capacitances of the resistors 405, 420 combine to form an effective parasitic capacitance, which is illustrated as the capacitor 425. Such an increase in capacitance increases the time constant of the RC circuit formed by the resistors 405, 420 and the capacitor 425. Increasing the time constant of the RC circuitry increases the settling time of the bias voltage and limits the bandwidth of the bias system 400. Advantageously, as further illustrated and described in FIGS. 5, 6, 7, and 8, a reference common mode voltage allows bias circuitry to divide the voltage across the feedback resistors without increasing parasitic capacitances.

FIG. 5 is a schematic diagram of a bias system 500 including a first example resistor 505, a second example resistor 510, and example bias circuitry 515. The example bias circuitry 515 of FIG. 5 includes a first example resistor 520, a second example resistor 525, a third example resistor 530, a fourth example resistor 535, and example buffer circuitry 540.

The bias system 500 has a first input, a second input, a first output, and a second output. The first input of the bias system 500 is structured to be coupled to an output of amplifier circuitry (e.g., the amplifier circuitry 120, 240 of FIGS. 1 and 2), which supplies the plus output signal (OUTP). The second input of the bias system 500 is structured to be coupled to an output of amplifier circuitry (e.g., the amplifier circuitry 120, 260 of FIGS. 1 and 2), which supplies the minus output signal (OUTM). The first output of the bias system 500 is structured to be coupled to an input of amplifier circuitry (e.g., the amplifier circuitry 120, 240), which receives a plus input signal (Vcmp). The second output of the bias system 500 is structured to be coupled to an input of amplifier circuitry (e.g., the amplifier circuitry 120, 240), which receives a minus input signal (Vcmm).

The resistor 505 has a first terminal, a second terminal, and a bias terminal. The first terminal of the resistor 505 is coupled to the resistor 520 and the first input of the bias system 500, which supplies the plus output signal. The second terminal of the resistor 505 is coupled to the first output of the bias system 500. The bias terminal of the resistor 505 is coupled to the resistors 520, 525.

The resistor 510 has a first terminal, a second terminal, and a bias terminal. The first terminal of the resistor 510 is coupled to the resistor 530 and the second input of the bias system 500, which supplies the minus output voltage. The second terminal of the resistor 510 is coupled to the second output of the bias system 500. The bias terminal of the resistor 510 is coupled to the resistor 530, 535. In the example of FIG. 5, the resistors 505, 510 are polysilicon resistors. In other examples, the resistors 505, 510 may be an alternative type of analog component integrated into an IC.

The bias circuitry 515 has a first input, a second input, a third input, a first output, and a second output. The first input of the bias circuitry 515 is coupled to the resistor 505 and the first input of the bias system 500, which supplies the plus output signal. The second input of the bias circuitry 515 is coupled to the resistor 510 and the second input of the bias system 500, which supplies the minus output signal. The third input of the bias circuitry 515 is coupled to a reference common mode terminal, which supplies a reference common mode voltage (Vcm). In some examples, the third input of the bias circuitry 515 is coupled to the common mode circuitry 160, 230 of FIGS. 1 and 2. In such examples, the common mode circuitry 160, 230 sets the reference common mode voltage equal to the common mode voltage of the inputs of the amplifier circuitry 120, 240. The first output of the bias circuitry 515 is coupled to the resistor 505, which receives a plus bias voltage (Vbias_P). The second output of the bias circuitry 515 is coupled to the resistor 510, which receives a minus bias voltage (Vbias_M).

The resistor 520 has a first terminal and a second terminal. The first terminal of the resistor 520 is coupled to the resistor 505 and the first input of the bias system 500, which supplies the plus output signal. The second terminal of the resistor 520 is coupled to the resistors 505, 525.

The resistor 525 has a first terminal and a second terminal. The first terminal of the resistor 525 is coupled to the resistors 505, 520. The second terminal of the resistor 525 is coupled to the resistor 535 and the buffer circuitry 540.

The resistor 530 has a first terminal and a second terminal. The first terminal of the resistor 530 is coupled to the second input of the bias system 500, which supplies the minus output signal. The second terminal of the resistor 530 is coupled to the resistors 510, 535.

The resistor 535 has a first terminal and a second terminal. The first terminal of the resistor 535 is coupled to the resistors 510, 530. The second terminal of the resistor 535 is coupled to the resistor 525 and the buffer circuitry 540.

The buffer circuitry 540 has an input and an output. The input of the buffer circuitry 540 is coupled to the third input of the bias circuitry 515, which supplies the reference common mode voltage. The output of the buffer circuitry 540 is coupled to the resistors 525, 535.

In example operations, the buffer circuitry 540 buffers the reference common mode voltage. In some examples, the buffer circuitry 540 isolates the reference common mode voltage from the resistors 520, 540. Also, the buffer circuitry 540 may buffer the reference common mode voltage by increasing the signal strength. The resistors 520, 525 produce the plus bias voltage responsive to dividing the difference between the plus output signal and the buffered common mode voltage. In some examples, the resistances of the resistors 520, 525 are equal, which sets the plus bias voltage evenly between the buffered common mode voltage and the voltage of the plus output signal. The resistors 530, 535 produce the minus bias voltage responsive to dividing the difference between the minus output signal and the buffered common mode voltage. In some examples, the resistances of the resistors 530, 535 are equal, which sets the minus bias voltage evenly between the buffered common mode voltage and the voltage of the minus output signal. Advantageously, the resistors 520, 525, 530, 535 bias the bodies (e.g., the body 320 of FIG. 3) based on the voltages of the plus and minus output signals and the reference common mode voltage. Advantageously, adjusting the plus and minus bias voltages based on the voltages of the plus and minus output signals reduces the first order voltage coefficient variations in the resistances of the resistors 505, 510. Example operations of the bias system 500 are further illustrated and described in connection with FIG. 9, below.

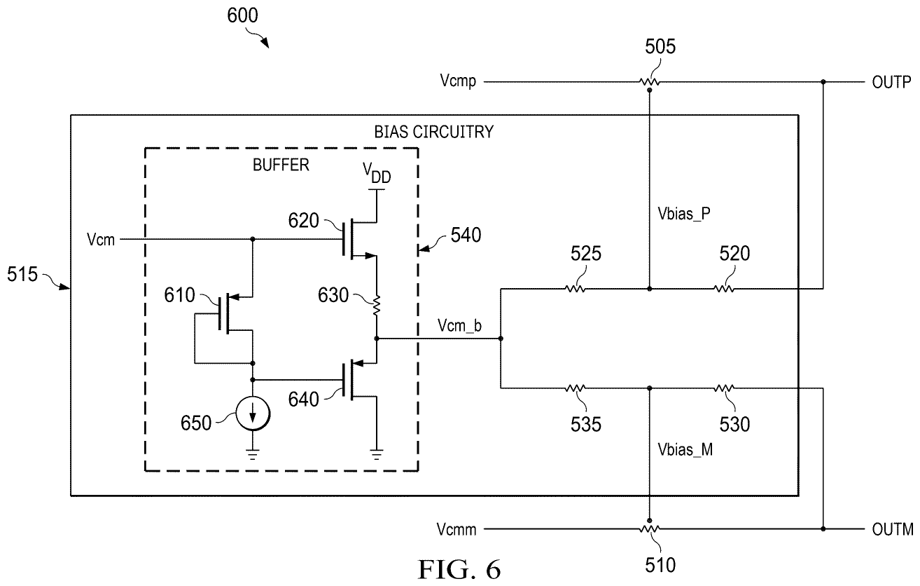

FIG. 6 is a schematic diagram of an example bias system 600 including the resistors 505, 510 of FIG. 5 and the bias circuitry 515 of FIG. 5. In the example of FIG. 6, the bias circuitry 515 includes the resistors 520, 525, 530, 535 of FIG. 5 and the buffer circuitry 540 of FIG. 5. The example buffer circuitry 540 of FIG. 6 includes a first example transistor 610, a second example transistor 620, an example resistor 630, a third example transistor 640, and example current source circuitry 650.

In the example of FIG. 6, the buffer circuitry 540 has an input and an output. The input of the buffer circuitry 540 is coupled to the reference common mode terminal, which supplies the reference common mode voltage (Vcm). The output of the buffer circuitry 540 is coupled to the resistors 525, 535, which receive a buffered common mode voltage (Vcm_b).

The transistor 610 has a first terminal, a second terminal, and a control terminal. The first terminal of the transistor 610 is coupled to the transistor 620 and the input of the buffer circuitry 540. The second and control terminals of the transistor 610 are coupled to the transistor 640 and the current source circuitry 650.

The transistor 620 has a first terminal, a second terminal, and a control terminal. The first terminal of the transistor 620 is coupled to a supply terminal, which supplies a supply voltage (e.g., V_{DD}). The second terminal of the transistor 620 is coupled to the resistor 630. The control terminal of the transistor 620 is coupled to the transistor 610 and the input of the buffer circuitry 540, which supplies the reference common mode voltage.

The resistor 630 has a first terminal and a second terminal. The first terminal of the resistor 630 is coupled to the transistor 620. The second terminal of the resistor 630 is coupled to the resistors 525, 535, the transistor 640, and the output of the buffer circuitry 540, which supplies the buffered common mode voltage.

The transistor 640 has a first terminal, a second terminal, and a control terminal. The first terminal of the transistor 640 is coupled to the resistors 525, 535, 630 and the output of the buffer circuitry 540, which supplies the buffered common mode voltage. The second terminal of the transistor 640 is coupled to a common terminal, which supplies the common potential (e.g., ground, AVSS, etc.). The control terminal of the transistor 640 is coupled to the transistor 610 and the current source circuitry 650.

The current source circuitry 650 has a first terminal and a second terminal. The first terminal of the current source circuitry 650 is coupled to the transistors 610, 640. The second terminal of the current source circuitry 650 is coupled to the common terminal, which supplies the common potential.

In the example of FIG. 6, the transistor 620 is an n-channel metal-oxide semiconductor field-effect transistor (MOSFET). Alternatively, the transistor 620 may be an n-channel field-effect transistor (FET), an n-channel insulated-gate bipolar transistor (IGBT), an n-channel junction field effect transistor (JFET), an NPN bipolar junction transistor (BJT) or, with slight modifications, a p-type equivalent device. In the example of FIG. 6, the transistors 610, 640 are p-channel MOSFETs. Alternatively, the transistors 610, 640 may be p-channel FETs, p-channel IGBTs, p-channel JFETs, PNP BJTs, or, with slight modifications, N-type equivalent devices. The transistors 610, 620, 640 may be depletion mode devices, drain-extended devices, enhancement mode devices, natural transistors or other type of device structure transistors. Furthermore, the transistors 610, 620, 640 may be implemented in/over a silicon substrate (Si), a silicon carbide substrate (SiC), a gallium nitride substrate (GaN) or a gallium arsenide substrate (GaAs).

In example operation, the transistors 620, 640 buffer the reference common mode voltage by sourcing or sinking current through the resistor 630. In an idle mode of operation, such as a lack of current across the resistors 520, 525, 530, 535, the resistor 630 reduces the idle current between the transistors 620, 640 by producing a voltage difference that sets the output of the buffer circuitry 540. In a transition between the idle mode and normal operation, the transistor 610 decreases distortion resulting from both of the transistors 620, 640 turning on or off. Advantageously, the transistor 610 and the resistor 630 reduce the idle current consumption and reduce distortions of the buffer circuitry 540. Example operations of the bias system 600 are further illustrated and described in connection with FIG. 9, below.

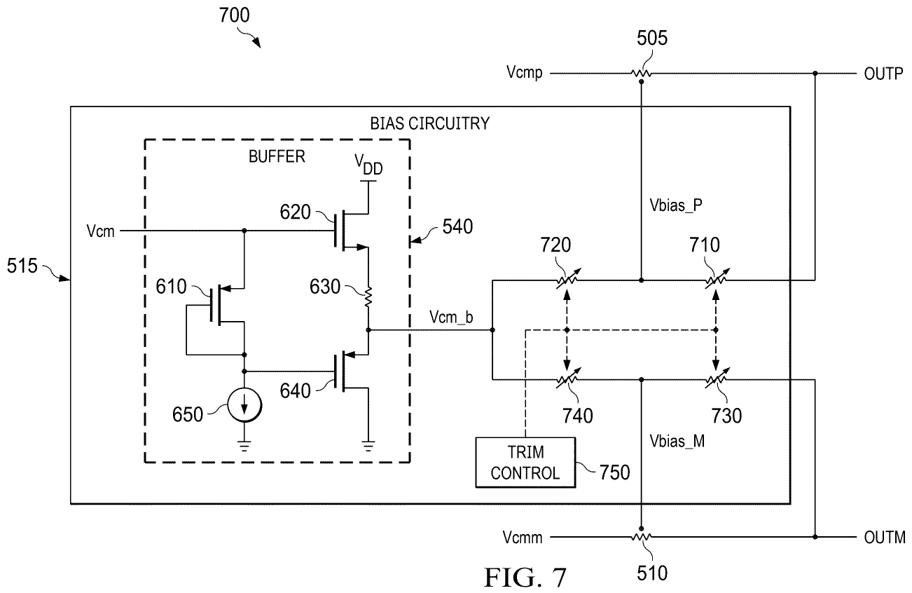

FIG. 7 is a schematic diagram of an example bias system 700 including the resistors 505, 510 of FIGS. 5 and 6 and the bias circuitry 515 of FIGS. 5 and 6. In the example of FIG. 7, the bias circuitry 515 includes the buffer circuitry 540 of FIGS. 5 and 6, a first resistor 710, a second resistor 720, a third resistor 730, a fourth resistor 740, and trim control circuitry 750. The example buffer circuitry 540 of FIG. 7 includes the transistors 610, 620, 640 of FIG. 6, the resistor 630 of FIG. 6, and the current source circuitry 650 of FIG. 6.

The bias system 700 has a first input, a second input, a first output, and a second output. The first input of the bias system 700 is structured to be coupled to an output of amplifier circuitry (e.g., the amplifier circuitry 120, 240 of FIGS. 1 and 2), which supplies the plus output signal (OUTP). The second input of the bias system 700 is structured to be coupled to an output of amplifier circuitry (e.g., the amplifier circuitry 120, 260 of FIGS. 1 and 2), which supplies the minus output signal (OUTM). The first output of the bias system 700 is structured to be coupled to an input of amplifier circuitry (e.g., the amplifier circuitry 120, 240), which receives a plus input signal (Vcmp). The second output of the bias system 700 is structured to be coupled to an input of amplifier circuitry (e.g., the amplifier circuitry 120, 240), which receives a minus input signal (Vcmm).

In the example of FIG. 7, the bias circuitry 515 has a first input, a second input, a third input, a first output, and a second output. The first input of the bias circuitry 515 is coupled to the resistor 505 and the first input of the bias system 700, which supplies the plus output signal. The second input of the bias circuitry 515 is coupled to the resistor 510 and the second input of the bias system 700, which supplies the minus output signal. The third input of the bias circuitry 515 is coupled to the reference common mode terminal, which supplies the reference common mode voltage (Vcm). In some examples, the third input of the bias circuitry 515 is coupled to the common mode circuitry 160, 230 of FIGS. 1 and 2. In such examples, the common mode circuitry 160, 230 set the reference common mode voltage equal to the common mode voltage of the inputs of the amplifier circuitry 120, 240. The first output of the bias circuitry 515 is coupled to the resistor 505, which receives a plus bias voltage (Vbias_P). The second output of the bias circuitry 515 is coupled to the resistor 510, which receives a minus bias voltage (Vbias_M).

The resistor 710 has a first terminal, a second terminal, and a control terminal. The first terminal of the resistor 710 is coupled to the resistor 505 and the first input of the bias circuitry 515. The second terminal of the resistor 710 is coupled to the resistors 505, 720. The control terminal of the resistor 710 is coupled to the trim control circuitry 750.

The resistor 720 has a first terminal, a second terminal, and a control terminal. The first terminal of the resistor 720 is coupled to the resistors 505, 710. The second terminal of the resistor 720 is coupled to the buffer circuitry 540 and the resistor 740. The control terminal of the resistor 720 is coupled to the trim control circuitry 750.

The resistor 730 has a first terminal, a second terminal, and a control terminal. The first terminal of the resistor 730 is coupled to the resistor 510 and the second input of the bias circuitry 515. The second terminal of the resistor 730 is coupled to the resistors 510, 740. The control terminal of the resistor 730 is coupled to the trim control circuitry 750.

The resistor 740 has a first terminal, a second terminal, and a control terminal. The first terminal of the resistor 740 is coupled to the resistors 510, 730. The second terminal of the resistor 740 is coupled to the buffer circuitry 540 and the resistor 720. The control terminal of the resistor 740 is coupled to the trim control circuitry 750. In the example of FIG. 7, the resistors 710, 720, 730, 740 are variable resistors, which have resistances set by a trim code.

The trim control circuitry 750 has an output coupled to the resistors 710, 720, 730, 740. In some examples, the trim control circuitry 750 is memory circuitry, such as a register, structured to store a trim code. In such examples, the trim code is structured to set the resistances of the resistors 710, 720, 730, 740.

In the example of FIG. 7, the transistor 620 is an n-channel metal-oxide semiconductor field-effect transistor (MOSFET). Alternatively, the transistor 620 may be an n-channel field-effect transistor (FET), an n-channel insulated-gate bipolar transistor (IGBT), an n-channel junction field effect transistor (JFET), an NPN bipolar junction transistor (BJT) or, with slight modifications, a p-type equivalent device. In the example of FIG. 7, the transistors 610, 640 are p-channel MOSFETs. Alternatively, the transistors 610, 640 may be p-channel FETs, p-channel IGBTs, p-channel JFETs, PNP BJTs, or, with slight modifications, N-type equivalent devices. The transistors 610, 620, 640 may be depletion mode devices, drain-extended devices, enhancement mode devices, natural transistors or other type of device structure transistors. Furthermore, the transistors 610, 620, 640 may be implemented in/over a silicon substrate (Si), a silicon carbide substrate (SiC), a gallium nitride substrate (GaN) or a gallium arsenide substrate (GaAs).

In example operations, the resistors 710, 720, 730, 740 need to have a current that allows the plus and minus bias voltages to have a drive strength that can settle the voltage of the body (e.g., the body 320 of FIG. 3) of the resistors 505, 510. The parasitic capacitances between the body (e.g., the body 320) and the substrate (e.g., the substrate 315 of FIG. 3) sets the minimum drive strength needed to bias the resistors 505, 510. Relatively high current through the resistors 710, 720, 730, 740 increases the drive strength of the plus and minus bias voltages. However, increasing the current through the resistors 710, 720, 730, 740 increases the power consumption of the bias circuitry 515.

In example operations, increasing the resistance of the resistors 710, 720, 730, 740 decreases the current through the bias circuitry 515 and decreases power consumption. Since the parasitic capacitances of the resistors 505, 510 vary based on manufacturing conditions, several resistances of the resistors 710, 720, 730, 740 may be tested to determine an ideal tradeoff between the drive strength of relatively high currents and the power efficiency of relatively low currents. In the example of FIG. 7, the trim control circuitry 750 allows designers and manufacturers to adjust the resistances of the resistors 710, 720, 730, 740 to improve power efficiency. Advantageously, using variable resistances for the resistors 710, 720, 730, 740 allows systems to improve power efficiency without risking drive strength of the bias voltages. Example operations of the bias system 700 are further illustrated and described in connection with FIG. 9, below.

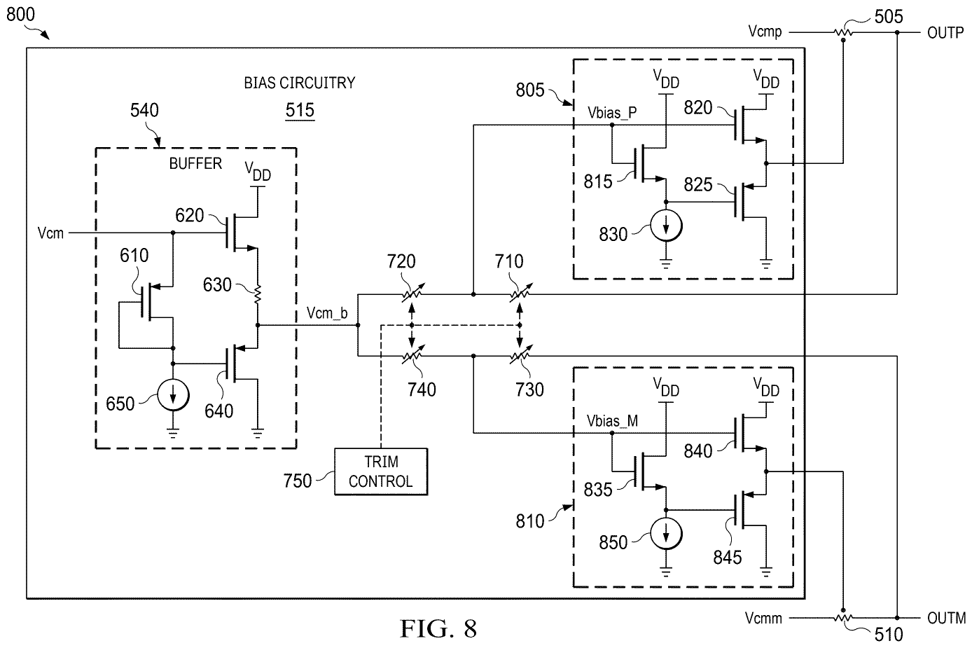

FIG. 8 is a schematic diagram of an example bias system 800 including the resistors 505, 510 of FIGS. 5, 6, and 7 and the bias circuitry 515 of FIGS. 5, 6, and 7. In the example of FIG. 8, the bias circuitry 515 includes the buffer circuitry 540 of FIGS. 5 and 6, the resistors 710, 720, 730, 740 of FIG. 7, the trim control circuitry 750 of FIG. 7, first buffer circuitry 805, and second buffer circuitry 810. The example buffer circuitry 540 of FIG. 8 includes the transistors 610, 620, 640 of FIGS. 6 and 7, the resistor 630 of FIGS. 6 and 7, and the current source circuitry 650 of FIGS. 6 and 7. The example buffer circuitry 805 of FIG. 8 includes a first example transistor 815, a second example transistor 820, a third example transistor 825, and example current source circuitry 830. The example buffer circuitry 810 of FIG. 8 includes a first example transistor 835, a second example transistor 840, a third example transistor 845, and example current source circuitry 850.

The bias system 800 has a first input, a second input, a first output, and a second output. The first input of the bias system 800 is structured to be coupled to an output of amplifier circuitry (e.g., the amplifier circuitry 120, 240 of FIGS. 1 and 2), which supplies the plus output signal (OUTP). The second input of the bias system 800 is structured to be coupled to an output of amplifier circuitry (e.g., the amplifier circuitry 120, 260 of FIGS. 1 and 2), which supplies the minus output signal (OUTM). The first output of the bias system 800 is structured to be coupled to an input of amplifier circuitry (e.g., the amplifier circuitry 120, 240), which receives a plus input signal (Vcmp). The second output of the bias system 800 is structured to be coupled to an input of amplifier circuitry (e.g., the amplifier circuitry 120, 240), which receives a minus input signal (Vcmm).

In the example of FIG. 8, the bias circuitry 515 has a first input, a second input, a third input, a first output, and a second output. The first input of the bias circuitry 515 is coupled to the resistor 505 and the first input of the bias system 800, which supplies the plus output signal. The second input of the bias circuitry 515 is coupled to the resistor 510 and the second input of the bias system 800, which supplies the minus output signal. The third input of the bias circuitry 515 is coupled to the reference common mode terminal, which supplies the reference common mode voltage (Vcm). In some examples, the third input of the bias circuitry 515 is coupled to the common mode circuitry 160, 230 of FIGS. 1 and 2. In such examples, the common mode circuitry 160, 230 set the reference common mode voltage equal to the common mode voltage of the inputs of the amplifier circuitry 120, 240. The first output of the bias circuitry 515 is coupled to the resistor 505, which receives a plus bias voltage (Vbias_P). The second output of the bias circuitry 515 is coupled to the resistor 510, which receives a minus bias voltage (Vbias_M).

The buffer circuitry 805 has an input and an output. The input of the buffer circuitry 805 is coupled to the resistors 710, 720. The output of the buffer circuitry 805 is coupled to the resistor 505 and the first output of the bias circuitry 515.

The buffer circuitry 810 has an input and an output. The input of the buffer circuitry 810 is coupled to the resistors 730, 740. The output of the buffer circuitry 810 is coupled to the resistor 510 and the second output of the bias circuitry 515.

The transistor 815 has a first terminal, a second terminal, and a control terminal. The first terminal of the transistor 815 is coupled to the supply terminal, which supplies the supply voltage. The second terminal of the transistor 815 is coupled to the transistor 825 and the current source circuitry 830. The control terminal of the transistor 815 is coupled to the resistors 710, 720 and the transistor 820.

The transistor 820 has a first terminal, a second terminal, and a control terminal. The first terminal of the transistor 820 is coupled to the supply terminal, which supplies the supply voltage. The second terminal of the transistor 820 is coupled to the resistor 505, the transistor 825, and the first output of the bias circuitry 515. The control terminal of the transistor 820 is coupled to the resistors 710, 720 and the transistors 815.

The transistor 825 has a first terminal, a second terminal, and a control terminal. The first terminal of the transistor 825 is coupled to the resistor 505, the transistor 820, and the first output of the bias circuitry 515. The second terminal of the transistor 825 is coupled to the common terminal, which supplies the common potential. The control terminal of the transistor 825 is coupled to the transistor 815 and the current source circuitry 830.

The current source circuitry 830 has a first terminal and a second terminal. The first terminal of the current source circuitry 830 is coupled to the transistors 815, 825. The second terminal of the current source circuitry 830 is coupled to the common terminal, which supplies the common potential.

The transistor 835 has a first terminal, a second terminal, and a control terminal. The first terminal of the transistor 835 is coupled to the supply terminal, which supplies the supply voltage. The second terminal of the transistor 835 is coupled to the transistor 845 and the current source circuitry 850. The control terminal of the transistor 835 is coupled to the resistors 730, 740 and the transistor 840.

The transistor 840 has a first terminal, a second terminal, and a control terminal. The first terminal of the transistor 840 is coupled to the supply terminal, which supplies the supply voltage. The second terminal of the transistor 840 is coupled to the resistor 510, the transistor 845, and the second output of the bias circuitry 515. The control terminal of the transistor 840 is coupled to the resistors 730, 740 and the transistors 835.

The transistor 845 has a first terminal, a second terminal, and a control terminal. The first terminal of the transistor 845 is coupled to the resistor 510, the transistor 840, and the second output of the bias circuitry 515. The second terminal of the transistor 845 is coupled to the common terminal, which supplies the common potential. The control terminal of the transistor 845 is coupled to the transistor 835 and the current source circuitry 850.

The current source circuitry 850 has a first terminal and a second terminal. The first terminal of the current source circuitry 850 is coupled to the transistors 835, 845. The second terminal of the current source circuitry 850 is coupled to the common terminal, which supplies the common potential.

In the example of FIG. 8, the transistors 620, 815, 820, 835, 840 are n-channel MOSFETs. Alternatively, the transistors 620, 815, 820, 835, 840 may be n-channel FETs, n-channel IGBTs, n-channel JFETs, NPN BJTs or, with slight modifications, p-type equivalent devices. In the example of FIG. 8, the transistors 610, 640, 825, 845 are p-channel MOSFETs. Alternatively, the transistors 610, 640, 825, 845 may be p-channel FETs, p-channel IGBTs, p-channel JFETs, PNP BJTs, or, with slight modifications, N-type equivalent devices. The transistors 610, 620, 640, 815, 820, 825 835, 840, 845 may be depletion mode devices, drain-extended devices, enhancement mode devices, natural transistors or other type of device structure transistors. Furthermore, the transistors 610, 620, 640, 815, 820, 825 835, 840, 845 may be implemented in/over a silicon substrate (Si), a silicon carbide substrate (SiC), a gallium nitride substrate (GaN) or a gallium arsenide substrate (GaAs).

In example operation, the transistors 820, 825 buffer the plus bias voltage from the resistors 710, 720 and the transistors 840, 845 buffer the minus bias voltage from the resistors 730, 740. In such example operations, the buffer circuitry 805, 810 uses current from the supply terminal to produce an output having a drive strength independent of the drive strength at the input. Unlike in the example of FIG. 7, where the resistances of the resistors 710, 720, 730, 740 are limited by the drive strength of the plus and minus bias voltages, in the example of FIG. 8, the buffer circuitry 805, 810 increases the drive strength. Advantageously, the buffer circuitry 805, 810 allows the trim control circuitry 750 to increase the resistances of the resistors 710, 720, 730, 740. Advantageously, increasing the resistances of the resistors 710, 720, 730, 740 reduces current and improves power efficiency of the bias circuitry 515. Example operations of the bias system 800 are further illustrated and described in connection with FIG. 9.

FIG. 9 is a flowchart representative of example machine-readable instructions or example operations 900 that may be at least one of executed, instantiated, or performed using example implementations of the bias circuitry 150, 225, 310, 515 of FIGS. 1, 2, 3, 5, 6, 7, and 8 or more generally the bias systems 300, 500, 600, 700, 800 of FIGS. 3, 5, 6, 7, 8, or even more generally the amplifier system 100 of FIG. 1 or the audio system 200 of FIG. 2.

In some examples, as illustrated by the dashed outline, the operations 900 of FIG. 9 begin at Block 910 at which the buffer circuitry 540 of FIGS. 5, 6, and 7 determines if there is current at a first or second output. In some examples, such as in FIGS. 6, 7, and 8, the buffer circuitry 540 is low idle current buffer circuitry, which buffers the reference common mode voltage responsive to a current at the output of the buffer circuitry 540. In example operation, the transistors 620, 640 of FIGS. 6, 7, and 8 buffer the reference common mode voltage (Vcm) at the input of the buffer circuitry 540. In idle operations, such as when there is no current through the resistors 525, 535, 720, 740 of FIGS. 5, 6, 7, and 8, the idle current between the transistors 620, 640 generates a voltage difference across the resistor 630 of FIG. 6. If the buffer circuitry 540 determines that there is no current at the first or second outputs (e.g., Block 910 returns a result of NO), control proceeds to return to Block 910.

Advantageously, the resistor 630 reduces the idle current of the buffer circuitry 540. Advantageously, reducing the idle current of the buffer circuitry 540 increases the power efficiency of the bias systems 500, 600, 700, 800. Advantageously, the transistor 610 of FIGS. 6, 7, and 8 reduces distortions between the turning on and off of the transistors 620, 640. Advantageously, reducing distortions between switching of the transistor 620, 640 improves the sound to noise ratio of the bias systems 500, 600, 700, 800. In some examples, the buffer circuitry 540 may not be low idle current buffer circuitry, such as not including the transistor 610 or the resistor 630. In such examples, the operations 900 may begin at Block 920.

If the buffer circuitry 540 determines that there is current at the first or second outputs (e.g., Block 910 returns a result of YES), the buffer circuitry 540 buffers a reference common mode voltage. (Block 920). In example normal operations, such as when there is current through the resistors 525, 535, 720, 740, the transistors 620, 640 supply current to set the output of the buffer circuitry 540 equal to the reference common mode voltage minus the gate-to-source voltage of the transistor 620. In some examples, such as in FIGS. 1 and 2, the common mode circuitry 160, 230 of FIGS. 1 and 2 set the reference common mode voltage equal to the common mode voltage of the input signals. In other examples, the reference common mode voltage is a fixed voltage representing a target common mode voltage of the input signals or the output signals.

The resistors 520, 525, 710, 720 of FIGS. 5, 6, 7, and 8 generate a first bias voltage between the common mode voltage and a first output voltage. (Block 930). In example operations, the resistors 520, 525, 710, 720 generate the plus bias voltage (Vbias_P) responsive to dividing the voltage difference between the plus output signal (OUTP) and the buffered common mode voltage (Vcm_b). In some examples, the resistances of the resistors 520, 525, 710, 720 are equal. In such examples, the resistors 520, 525, 710, 720 set the plus bias voltage equal to a voltage halfway between the buffered common mode voltage and the plus output signal.

As illustrated by the dashed outline, in some examples, the buffer circuitry 805 of FIG. 8 buffers the first bias voltage. (Block 940). In example operations, the transistors 820, 825 of FIG. 8 buffer the plus bias voltage from the resistors 520, 525, 710, 720. In such example operations, the transistors 820, 825 drive the bias terminal of the resistor 505 using current from the supply terminal. In some examples, the transistors 820, 825 may increase the drive strength of currents driving the plus bias voltage. In such examples, increasing the resistances of the resistors 520, 525, 710, 720 decreases the current of the plus bias voltage and the buffer circuitry 805 boosts the drive strength at the bias terminal of the resistor 505. Advantageously, increasing the resistances of the resistors 520, 525, 710, 720 decreases the current through the bias circuitry 515. Advantageously, decreasing the current through the bias circuitry 515 increases the power efficiency.

The bias circuitry 515 biases a first feedback resistor using the first bias voltage. (Block 950). In example operation, the bias circuitry 515 sets the corresponding body (e.g., the body 320 of FIG. 3) of the resistor 505 to one of the plus bias voltage or a buffered plus bias voltage. In some examples, the resistances of the resistors 520, 525, 710, 720 are structured to provide a drive strength (e.g., current) that can charge and discharge parasitic capacitances between the body (e.g., the body 320) and substrate (e.g., the substrate 315 of FIG. 3). Advantageously, biasing the resistor 505 to a voltage between the voltages at the first and second terminals of the resistor 505 reduces variation in resistance responsive to the first order voltage coefficient. Advantageously, reducing variations in the resistance of the resistor 505 reduces total harmonic distortions resulting from changes in the gain of the amplifier system 100 or the audio system 200.

The resistors 530, 535, 730, 740 of FIGS. 5, 6, 7, and 8 generate a second bias voltage between the common mode voltage and a second output voltage. (Block 960). In example operations, the resistors 530, 535, 730, 740 generate the minus bias voltage (Vbias_M) responsive to dividing the voltage difference between the minus output signal (OUTM) and the buffered common mode voltage (Vcm_b). In some examples, the resistances of the resistors 530, 535, 730, 740 are equal. In such examples, the resistors 530, 535, 730, 740 set the minus bias voltage equal to a voltage half way between the buffered common mode voltage and the minus output signal.

As illustrated by the dashed outline, in some examples, the buffer circuitry 810 of FIG. 8 buffers the second bias voltage. (Block 970). In example operations, the transistors 840, 845 of FIG. 8 buffer the plus bias voltage from the resistors 530, 535, 730, 740. In such example operations, the transistors 840, 845 drive the bias terminal of the resistor 510 using current from the supply terminal. In some examples, the transistors 840, 845 may increase the drive strength of currents driving the plus bias voltage. In such examples, increasing the resistances of the resistors 530, 535, 730, 740 decreases the current of the plus bias voltage and the buffer circuitry 810 boosts the drive strength at the bias terminal of the resistor 510. Advantageously, increasing the resistances of the resistors 530, 535, 730, 740 decreases the current through the bias circuitry 515. Advantageously, decreasing the current through the bias circuitry 515 increases the power efficiency.

The bias circuitry 515 biases a second feedback resistor using the second bias voltage. (Block 980). In example operation, the bias circuitry 515 sets the corresponding body (e.g., the body 320) of the resistor 510 to one of the minus bias voltage or a buffered minus bias voltage. In some examples, the resistances of the resistors 530, 535, 730, 740 are structured to provide a drive strength (e.g., current) that can charge and discharge parasitic capacitances between the body (e.g., the body 320) and substrate (e.g., the substrate 315). Advantageously, biasing the resistor 510 to a voltage between the voltages at the first and second terminals of the resistor 510 reduces variation in resistance responsive to the first order voltage coefficient. Advantageously, reducing variations in the resistance of the resistor 510 reduces total harmonic distortions resulting from changes in the gain of the amplifier system 100 or the audio system 200. Control proceeds to return to Block 910.

Example methods are described with reference to the flowchart illustrated in FIG. 9. However, many other methods of implementing the bias circuitry 150, 225, 310, 415, 515 of FIGS. 1, 2, 3, 4, 5, 6, 7, and 8 or more generally the bias systems 300, 400, 500, 600, 700, 800 of FIGS. 3, 4, 5, 6, 7, 8, or event more generally the amplifier system 100 of FIG. 1 or the audio system 200 of FIG. 2 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

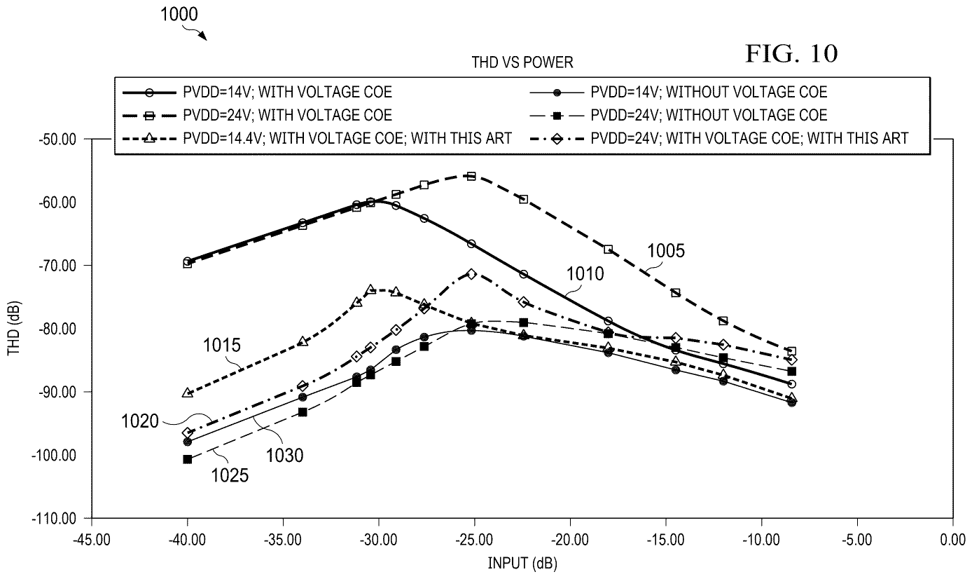

FIG. 10 is a plot 1000 of example total harmonic distortion (THD) versus power of feedback resistors with and without the bias circuitry 150, 225, 310, 515 of FIGS. 1, 2, 3, 5, 6, 7, and 8. The example plot 1000 of FIG. 10 includes a first example THD 1005, a second example THD 1010, a third example THD 1015, a fourth example THD 1020, a first target THD 1025, and a second target THD 1030.

The first THD 1005 illustrates the total harmonic distortion of the audio system 200 responsive to the first and second order voltage coefficients of the resistances of the resistors 245, 250 of FIG. 2 at a first supply voltage. The second THD 1010 illustrates the total harmonic distortion of the audio system 200 responsive to the first and second voltage coefficients of the resistances of the resistors 245, 250 at a second supply voltage. In the example of FIG. 10, the second supply voltage is greater than the first supply voltage. Both of the THDs 1005, 1010 are illustrated without compensation from the bias circuitry 150, 225, 310, 515.

The third THD 1015 illustrates the total harmonic distortion of the audio system 200 with the bias circuitry 150, 225, 310, 515 compensating the bias voltage for the first order voltage coefficient at the first supply voltage. The fourth THD 1020 illustrates the total harmonic distortion of the audio system 200 with the bias circuitry 150, 225, 310, 515 compensating the bias voltage for the first order voltage coefficient at the second supply voltage. Advantageously, the bias circuitry 150, 225, 310, 515 reduces the THD of the audio system 200.

The first target THD 1025 illustrates the total harmonic distortion of the audio system 200 responsive to the resistors 245, 250 having either the first or second order voltage coefficients modifications to the resistances at the first supply voltage. The second target THD 1030 illustrates the total harmonic distortion of the audio system 200 responsive to the resistors 245, 250 having either the first or second order voltage coefficients modifications to the resistances at the second supply voltage. Advantageously, compensating for the first order voltage coefficient of the resistors 245, 250 using the bias circuitry 150, 225, 310, 515 reduces the THD of the audio system 200.

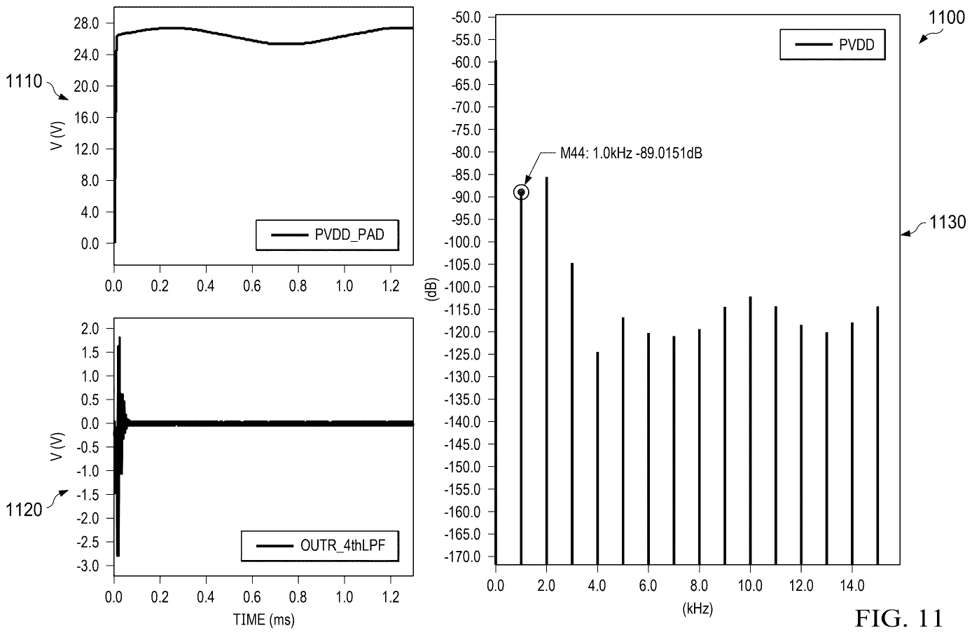

FIG. 11 is a plot 1100 of example power supply rejection ratio (PSRR) with the bias circuitry 150, 225, 310, 515 of FIGS. 1, 2, 3, 5, 6, 7, and 8. The example plot 1100 of FIG. 11 includes a power supply noise signal 1110, an output signal 1120, and a frequency response 1130.

The power supply noise signal 1110 illustrates an example power supply voltage of the audio system 200 with low frequency noise. In the example of FIG. 11, the power supply noise signal 1110 has noise having a frequency of approximately one kilohertz (kHz), which is in the audible frequency range. The output signal 1120 illustrates an example output of the audio system 200 without an input audio signal. The frequency response 1130 illustrates a discrete Fourier transform (dft) of frequencies at the output of the audio system 200 responsive to the power supply noise signal 1110. Advantageously, the noise at the frequency of the power supply noise signal 1110 is within an acceptable level. Advantageously, setting the bias terminals of the resistors 245, 250 using the bias circuitry 150, 225, 310, 515 improves the PSRR of the audio system 200.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing at least one of a semiconductor device (e.g., a transistor), a semiconductor die containing a semiconductor device, or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. Semiconductor devices are often used in orientation different than their orientation during fabrication. Thus, when referring to one of or a combination of a semiconductor device (e.g., a transistor), a semiconductor die containing a semiconductor device, or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein, integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

What is claimed is:

1. An apparatus comprising:
a first resistor having a first terminal and a bias terminal;
a second resistor having a first terminal and a bias terminal; and
bias circuitry including:
a third resistor having a first terminal and a second terminal, the first terminal of the third resistor coupled to the first terminal of the first resistor;
a fourth resistor having a first terminal and a second terminal, the first terminal of the fourth resistor coupled to the bias terminal of the first resistor and the second terminal of the third resistor;
a fifth resistor having a first terminal and a second terminal, the first terminal of the fifth resistor coupled to the first terminal of the second resistor;
a sixth resistor having a first terminal and a second terminal, the first terminal of the sixth resistor coupled to the bias terminal of the second resistor and the second terminal of the fifth resistor; and
buffer circuitry having an output coupled to the second terminal of the fourth resistor and the second terminal of the sixth resistor.

2. The apparatus of claim 1, wherein the first resistor is a polysilicon resistor including:
a substrate coupled to the bias terminal, the substrate having a doped well region coupled to the bias terminal of the first resistor; and
a polysilicon layer over the doped well region of the substrate, the polysilicon layer coupled to the first terminal of the first resistor.

3. The apparatus of claim 1, wherein the buffer circuitry includes:
a first transistor having a first terminal, a second terminal and a control terminal;
a second transistor having a first terminal and a control terminal, the control terminal of the second transistor coupled to the first terminal of the first transistor;
a seventh resistor having a first terminal and a second terminal, the first terminal of the seventh resistor coupled to the first terminal of the second transistor; and
a third transistor having a first terminal and a control terminal, the first terminal of the third transistor coupled to the second terminal of the fourth resistor and the second terminal of the sixth resistor, the control terminal of the third transistor coupled to the second terminal of the first transistor, and the control terminal of the first transistor.

4. The apparatus of claim 3, wherein the buffer circuitry is further including current source circuitry having a terminal coupled to the second terminal of the first transistor, the control terminal of the second transistor, and the control terminal of the third transistor.

5. The apparatus of claim 1, wherein the buffer circuitry is first buffer circuitry, and the apparatus further comprising:
second buffer circuitry having an input and an output, the input of the second buffer circuitry coupled to the second terminal of the third resistor and the first terminal of the fourth resistor, the output of the second buffer circuitry coupled to the bias terminal of the first resistor; and
third buffer circuitry having an input and an output, the input of the third buffer circuitry coupled to the second terminal of the fifth resistor and the first terminal of the sixth resistor, the output of the second buffer circuitry coupled to the bias terminal of the second resistor.

6. The apparatus of claim 5, wherein the second buffer circuitry includes:
a first transistor having a first terminal and a control terminal;
a second transistor having a first terminal and a control terminal, the control terminal of the second transistor coupled to the second terminal of the third resistor, the first terminal of the fourth resistor, and the control terminal of the first transistor; and
a third transistor having a first terminal and a control terminal, the first terminal of the third transistor coupled to the bias terminal of the first resistor and the first terminal of the second transistor, the control terminal of the third transistor coupled to the first terminal of the first transistor.

7. The apparatus of claim 1, wherein the first resistor further has a second terminal, the second resistor further has a second terminal, and the apparatus further comprising amplifier circuitry having a first input, a second input, a first output, and a second output, the first input of the amplifier circuitry coupled to the second terminal of the first resistor, the second input of the amplifier circuitry coupled to the second terminal of the second resistor, the first output of the amplifier circuitry coupled to the first terminal of the first resistor and the first terminal of the third resistor, the second output of the amplifier circuitry coupled to the first terminal of the second resistor and the first terminal of the fifth resistor.

8. The apparatus of claim 7, wherein the buffer circuitry further has an input, and the apparatus is further comprising common mode circuitry having a first input, a second input, and an output, the first input of the common mode circuitry coupled to the second terminal of the first resistor and the first input of the amplifier circuitry, the second input of the common mode circuitry coupled to the second terminal of the second resistor and the second input of the amplifier circuitry, the output of the common mode circuitry coupled to the input of the buffer circuitry.

9. The apparatus of claim 1, wherein the first resistor further has a second terminal, the second resistor further has a second terminal, and the apparatus further comprising multi-class modulation circuitry including:
first amplifier circuitry having a first input, a second input, and an output, the first input of the first amplifier circuitry coupled to the second terminal of the first resistor, the second input of the first amplifier circuitry coupled to the second terminal of the second resistor, the output of the first amplifier circuitry coupled to the first terminal of the first resistor and the first terminal of the third resistor; and
second amplifier circuitry having an output coupled to the first terminal of the second resistor and the first terminal of the fifth resistor.

10. An apparatus comprising:
amplifier circuitry having a first input, a second input, a first output, and a second output;
a first resistor having a first terminal, a second terminal, and a bias terminal, the first terminal of the first resistor coupled to the first input of the amplifier circuitry;
a second resistor having a first terminal, a second terminal, and a bias terminal, the first terminal of the second resistor coupled to the second input of the amplifier circuitry; and
bias circuitry having a first input, a second input, a first output, and a second output, the first input of the bias circuitry coupled to the first output of the amplifier circuitry and the second terminal of the first resistor, the second input of the bias circuitry coupled to the second output of the amplifier circuitry and the second terminal of the second resistor, the first output of the bias circuitry coupled to the bias terminal of the first resistor, the second output of the bias circuitry coupled to the bias terminal of the second resistor.

11. The apparatus of claim 10, further comprising a third resistor having a first terminal, a second terminal, and a bias terminal, the first terminal of the third resistor coupled to the first input of the amplifier circuitry, the second terminal of the third resistor coupled to the first terminal of the first resistor, the bias terminal of the first resistor, and the bias terminal of the third resistor.

12. The apparatus of claim 10, wherein the bias circuitry includes:
a third resistor having a first terminal and a second terminal, the first terminal of the third resistor coupled to the first output of the amplifier circuitry and the second terminal of the first resistor;
a fourth resistor having a first terminal and a second terminal, the first terminal of the fourth resistor coupled to the bias terminal of the first resistor and the second terminal of the third resistor;
a fifth resistor having a first terminal and a second terminal, the first terminal of the fifth resistor coupled to the second output of the amplifier circuitry and the second terminal of the second resistor; and
a sixth resistor having a first terminal and a second terminal, the first terminal of the sixth resistor coupled to the bias terminal of the second resistor and the second terminal of the fifth resistor, the second terminal of the sixth resistor coupled to the second terminal of the fourth resistor.

13. The apparatus of claim 12, wherein the bias circuitry is further including buffer circuitry including:
a first transistor having a first terminal, a second terminal, and a control terminal;
a second transistor having a first terminal and a control terminal, the control terminal of the second transistor coupled to the first terminal of the first transistor;
a seventh resistor having a first terminal and a second terminal, the first terminal of the seventh resistor coupled to the first terminal of the second transistor; and
a third transistor having a first terminal and a control terminal, the first terminal of the third transistor coupled to the second terminal of the fourth resistor and the second terminal of the sixth resistor, the control terminal of the third transistor coupled to the second terminal of the first transistor and the control terminal of the first transistor.

14. The apparatus of claim 12, the apparatus further comprising:
common mode circuitry having a first input, a second input, and an output; and
wherein the bias circuitry further including buffer circuitry having an input and an output, the input of the buffer circuitry coupled to the output of the common mode circuitry, the output of the buffer circuitry coupled to the second terminal of the fourth resistor and the second terminal of the sixth resistor.

15. The apparatus of claim 12, wherein the bias circuitry further includes:
first buffer circuitry having an input and an output, the input of the first buffer circuitry coupled to the second terminal of the third resistor and the first terminal of the fourth resistor, the output of the first buffer circuitry coupled to the bias terminal of the first resistor; and
second buffer circuitry having an input and an output, the input of the second buffer circuitry coupled to the second terminal of the fifth resistor and the first terminal of the sixth resistor, the output of the second buffer circuitry coupled to the bias terminal of the second resistor.

16. The apparatus of claim 10, wherein the first resistor is a polysilicon resistor including:
a substrate coupled to the bias terminal, the substrate having a doped well region coupled to the bias terminal of the first resistor; and
a polysilicon layer coupled over the doped well region of the substrate, the polysilicon layer coupled to the first terminal and the second terminal of the first resistor.

17. An apparatus comprising:
a first resistor having a first terminal and a bias terminal;
a second resistor having a first terminal and a bias terminal;
a third resistor having a first terminal and a second terminal, the first terminal of the third resistor coupled to the first terminal of the first resistor;
first buffer circuitry having an input and an output, the output of the first buffer circuitry coupled to the bias terminal of the first resistor;
a fourth resistor having a first terminal and a second terminal, the first terminal of the fourth resistor coupled to the second terminal of the third resistor and the input of the first buffer circuitry;
a fifth resistor having a first terminal and a second terminal, the first terminal of the fifth resistor coupled to the first terminal of the second resistor;
second buffer circuitry having an input and an output, the output of the second buffer circuitry coupled to the bias terminal of the second resistor; and
a sixth resistor having a first terminal and a second terminal, the first terminal of the sixth resistor coupled to the second terminal of the fifth resistor and the input of the fifth resistor, the second terminal of the sixth resistor coupled to the second terminal of the fourth resistor.

18. The apparatus of claim 17, further comprising third buffer circuitry having an output coupled to the second terminal of the fourth resistor and the second terminal of the sixth resistor.

19. The apparatus of claim 18, wherein the first resistor further has a second terminal, the second resistor further has a second terminal, and the apparatus further comprising amplifier circuitry having a first input, a second input, a first output, and a second output, the first input of the amplifier circuitry coupled to the second terminal of the first resistor, the second input of the amplifier circuitry coupled to the second input of the amplifier circuitry, the first output of the amplifier circuitry coupled to the first terminal of the first resistor and the first terminal of the third resistor, the second output of the amplifier circuitry coupled to the first terminal of the second resistor and the first terminal of the fifth resistor.

20. The apparatus of claim 17, wherein the first resistor is a polysilicon resistor including:
a substrate coupled to the bias terminal, the substrate having a doped well region coupled to the bias terminal of the first resistor; and
a polysilicon layer coupled over the doped well region of the substrate, the polysilicon layer coupled to the first terminal of the first resistor.
